(19) United States
(12) Patent Application Publication
(10) Pub. No.: US 2025/0047128 A1
(43) Pub. Date: Feb. 6, 2025

(54) SERVER SYSTEM AND SERVER INTEGRATED CABINET

(71) Applicant: Hebei Qinhuai Data Co., Limited., Zhangjiakou City (CN)

(72) Inventor: Binghua ZHANG, Zhangjiakou City (CN)

(21) Appl. No.: 18/792,317

(22) Filed: Aug. 1, 2024

(30) Foreign Application Priority Data
Aug. 4, 2023 (CN) 202310980603.1

(51) Int. Cl. H02J 7/35; H05K 7/20

(52) U.S. Cl. CPC H02J 7/35; H05K 7/20736

(57) ABSTRACT

The present disclosure discloses a server system and a server integrated cabinet, where the server system at least includes the server integrated cabinet and a solar cell array, and the server integrated cabinet includes an energy storage battery pack, a controller, and a load. The solar cell array, the energy storage battery pack, and the load are connected to the controller, respectively, such that the solar cell array and the energy storage battery pack supply power to the load.

### CROSS REFERENCE TO RELATED APPLICATION

This application claims priority to Chinese Patent Application No. 202310980603.1, titled “SERVER SYSTEM AND SERVER INTEGRATED CABINET” and filed to the China National Intellectual Property Administration on August 04, the entire contents of which are incorporated herein by reference.

### TECHNICAL FIELD

The present disclosure relates to the field of server device, and more particularly, to a server system and a server integrated cabinet.

### BACKGROUND

Existing power distribution solutions for outdoor server integrated cabinet adopt power grid lead-in, which does not meet requirements for green environmental protection and low-carbon emission reduction.

Moreover, in areas shortage of electricity, reliability of supply of power to servers cannot be guaranteed during electricity consumption peak, which adversely affects normal use of the servers.

### SUMMARY

An objective of the present disclosure is to provide a server system and a server integrated cabinet, to improve reliability of supply of power to the server integrated cabinet.

The present disclosure provides a server system. The server system at least includes the server integrated cabinet and a solar cell array, where the server integrated cabinet includes an energy storage battery pack, a controller, and a load. The solar cell array, the energy storage battery pack, and the load are connected to the controller, respectively, such that the solar cell array and the energy storage battery pack supply power to the load.

In an embodiment of the present disclosure, the solar cell array is connected to the controller by means of an anti-reverse charging diode, and the anti-reverse charging diode is configured to ensure an electric current to flow unidirectionally from the solar cell array to the controller.

In an embodiment of the present disclosure, the load includes a DC load; and the controller is connected to the DC load, and a first control switch is connected in series between the controller and the DC load.

In an embodiment of the present disclosure, the load includes an AC load; and the controller is connected to the AC load, and a second control switch and an inverter are connected in series between the controller and the AC load.

In an embodiment of the present disclosure, the server system also includes a backup energy source, where the backup energy source is connected to the controller to supply power to the load by means of the controller.

Correspondingly, the present disclosure also provides a server integrated cabinet. The server integrated cabinet includes a cabinet body, an energy storage battery pack, a controller, a fire protection component, a monitoring component, and a plurality of server bodies. The energy storage battery pack, the controller, the fire protection component, the monitoring component, and the plurality of server bodies are installed in the cabinet body. The energy storage battery pack is separately connected to the energy storage battery pack, the fire protection component, the monitoring component, and the plurality of server bodies by means of the controller. The fire protection component is configured to enable a fire protection function based on a first detection result from the monitoring component.

In an embodiment of the present disclosure, the server integrated cabinet also includes a refrigeration component, where the refrigeration component is connected to the energy storage battery pack and the controller, respectively. The refrigeration component is configured to control a temperature inside the cabinet body based on a second detection result from the monitoring component.

In an embodiment of the present disclosure, the server integrated cabinet also includes a UPS component. The energy storage battery pack and the external solar cell array are connected to the controller by means of the UPS component.

In an embodiment of the present disclosure, the energy storage battery pack, the controller, the refrigeration component, the UPS component, the fire protection component, the monitoring component, and the plurality of server bodies are arranged along a height direction of the cabinet body.

In an embodiment of the present disclosure, the monitoring component includes a temperature sensor and a smoke sensor.

Beneficial effects of the present disclosure are as below. Different from existing technologies, the present disclosure provides a server system and a server integrated cabinet. The server system includes a solar cell array and an energy storage battery pack inside the server integrated cabinet. The solar cell array and the energy storage battery pack work together with mains supply to supply power to the load, to alleviate pressure on a power grid during electricity consumption peak. Furthermore, the solar cell array and the energy storage battery pack provide temporary power supply in the event of a power outage, to prevent the server from stopping operating, thereby improving reliability of supply of power to the server integrated cabinet.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a server integrated cabinet according to an embodiment of the present disclosure;

FIG. 2 is a schematic diagram of a server system according to an embodiment of the present disclosure;

FIG. 3 is a schematic diagram of the server system according to another embodiment of the present disclosure;

FIG. 4 is a schematic diagram of the server system according to still another embodiment of the present disclosure; and

FIG. 5 is a schematic diagram of the server system according to still another embodiment of the present disclosure.

Reference numerals in the accompanying drawings:
server integrated cabinet 1; cabinet body 10; energy storage battery pack 11; controller 12; DC load 131; first control switch 1311; AC load 132; second control switch 1321; inverter 1322; backup energy source 14; fire protection component 15; monitoring component 16; server body 17; refrigeration component 18; UPS component 19; solar cell array 2; and anti-reverse charging diode 21.

### DETAILED DESCRIPTION

To make the objectives, technical solutions and advantages of the present disclosure clearer, the embodiments of the present disclosure will be further described in detail below with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal communication between two apparatuses, elements, or components. The specific significations of the above terms in the present disclosure may be understood in the light of specific conditions by persons of ordinary skill in the art.

The present disclosure provides a server system and a server integrated cabinet, which are described in detail below, respectively. It is to be noted that description order of the following embodiments does not limit preferred order of the embodiments of the present disclosure. In the foregoing embodiments, description of various embodiments may be focused on differentially, and reference may be made to related descriptions of other embodiments for a part not expatiated in a certain embodiment.

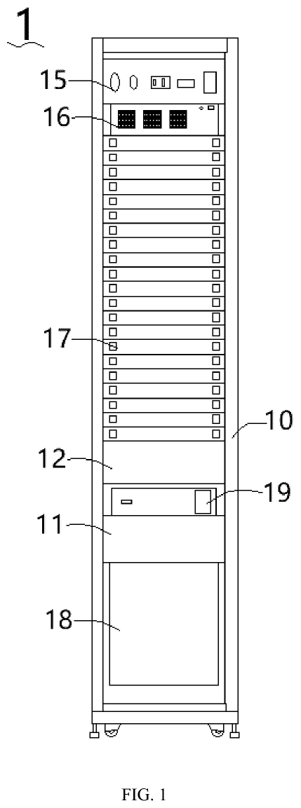

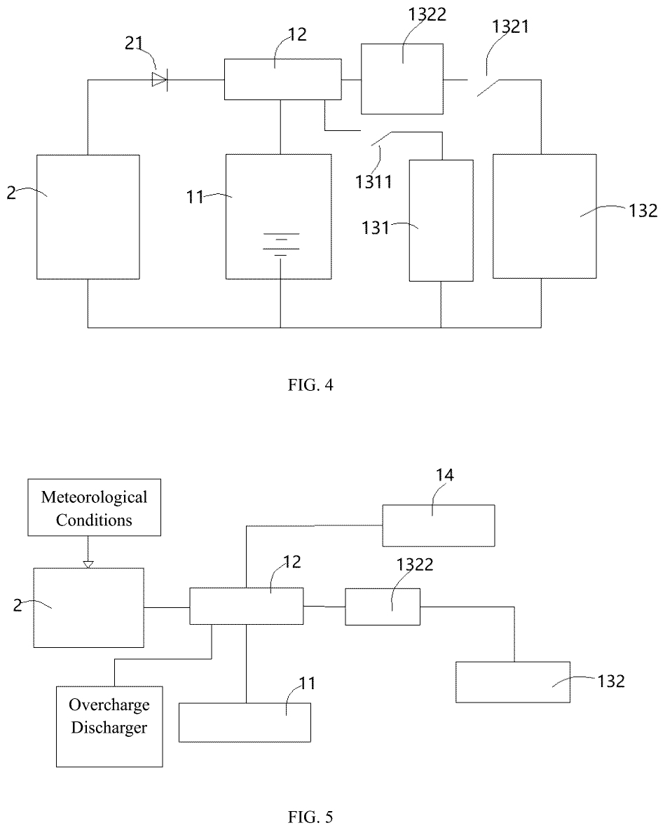

Referring to FIGS. 1 to 5 together, in one embodiment, the server system may at least include a server integrated cabinet 1 and a solar cell array 2. The server integrated cabinet 1 includes an energy storage battery pack 11, a controller 12, and a load. The solar cell array 2, the energy storage battery pack 11, and the load are connected to the controller 12, respectively. The controller 12 distributes power supplied by the solar cell array 2 and the energy storage battery pack 11 to the load, such that the solar cell array 2 and the energy storage battery pack 11 supply power to the load.

In this embodiment, the server system may also include mains power. The mains power serves as a main power supply for the server integrated cabinet 1. During off-peak electric supply, the solar cell array 2 and the mains power jointly supply power to the server integrated cabinet 1. In this period, the energy storage battery pack 11 is in a float charging mode to maintain state of charge of the energy storage battery pack 11 at a saturation level. During peak electricity consumption, the solar cell array 2 and the energy storage battery pack 11 may work together with the mains power to supply power to the load, to alleviate pressure on a power grid during the peak electricity consumption.

Of course, power may also be supplied to the load of the server integrated cabinet 1 only by means of the solar cell array 2 and the energy storage battery pack 11. Alternatively, in the event of a power outage of the mains power, power is supplied only by means of the solar cell array and the energy storage battery pack, to prevent the server from stopping operating, thereby improving reliability of supply of power to the server integrated cabinet.

It should be noted that in this embodiment, the solar cell array 2 and the energy storage battery pack 11 work together with the mains supply to supply power to the load, to alleviate the pressure on the power grid during the electricity consumption peak. Furthermore, the solar cell array 2 and the energy storage battery pack 11 provide temporary power supply in the event of the power outage, to prevent the server from stopping operating, thereby improving the reliability of supply of power to the server integrated cabinet. Furthermore, use of photovoltaic power generation is more advantageous to green energy saving and low-carbon emission reduction.

It should be pointed out that the solar cell array 2 is a system comprised of a plurality of solar cell panels connected in parallel or in series. These solar cell panels are installed together and are connected together to form a large solar cell module. Each of the solar cell panels generally is comprised of a plurality of silicon chips, and can convert solar energy into electrical energy when exposed to sunlight to output direct current.

In practical applications, the solar cell array 2 is connected to the controller 12 by means of the anti-reverse charging diode 21. As a component for protecting a circuit, the anti-reverse charging diode 21 has unidirectional conductivity, such that an electric current flows unidirectionally from the solar cell array 2 to the controller 12, avoiding reverse flow of the electric current to the solar cell array 2, thus preventing causing damage to the solar cell array 2.

The above load refers to a power consuming component in the server integrated cabinet 1, such as a fire protection component 15, a monitoring component 16, a plurality of server bodies 17, and a refrigeration component 18. The load generally includes a DC load 131 and an AC load 132.

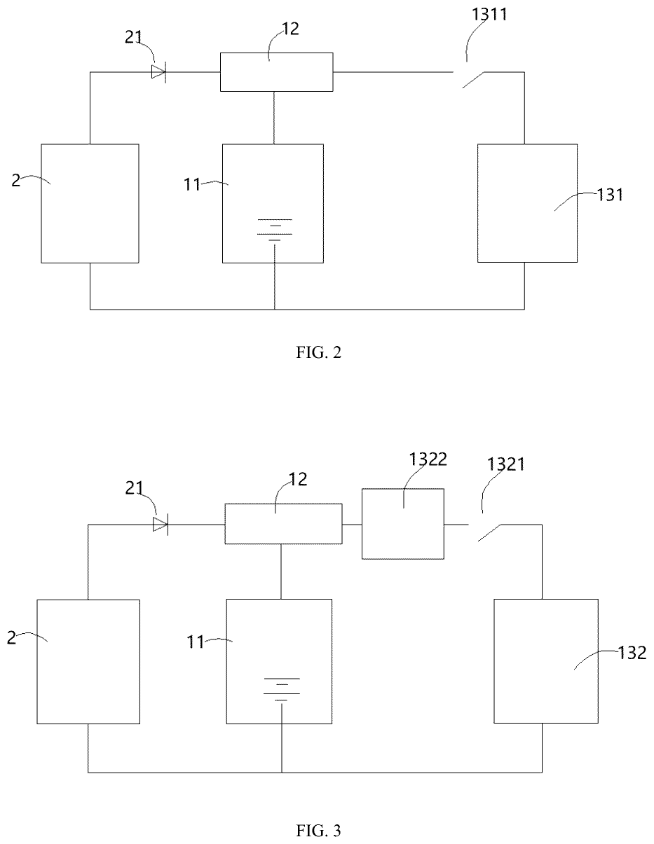

When the load includes the DC load 131, as shown in FIG. 2, the controller 12 is connected to the DC load 131 and can directly supply power to the DC load 131. A first control switch 1311 should also be connected in series between the controller 12 and the DC load 131, and the first control switch 1311 is configured to control on/off between the DC load 131 and the controller 12.

When the load includes the AC load 132, as shown in FIG. 3, the controller 12 is connected to the AC load 132, and an inverter 1322 is connected in series between the controller 12 and the AC load 132. The inverter 1322 converts a direct current distributed by the controller 12 into an alternating current for use by the AC load 132. Of course, a second control switch 1321 should be connected in series between the controller 12 and the AC load 132. The second control switch 1321 controls on/off between the AC load 132 and the controller 12 for power interruption during maintenance.

When the load includes both the DC load 131 and the AC load 132, as shown in FIG. 3, on the basis of the above implementation solutions, the DC load 131 and the AC load 132 should be connected in parallel.

As shown in FIG. 5, in one embodiment, the server system also includes a backup energy source 14. The backup energy source 14 is connected to the controller 12 to supply power to the load by means of the controller 12. The backup energy source 14 should be understood as below: when the mains power, the solar cell array 2, and the energy storage battery pack 11 cannot meet power supply demands, the backup energy source 14 is started to supply power. The backup energy source 14 may be a diesel generator, a wind turbine generator, a gas generator set, and so on, which is not to be enumerated in the present disclosure.

Reference may be made to FIG. 1 again for the specific structure of the server integrated cabinet 1. In one embodiment, the server integrated cabinet 1 may include a cabinet body 10, and the energy storage battery pack 11, the controller 12, the fire protection component 15, the monitoring component 16, and the plurality of server bodies 17. The cabinet body 10 serves as a carrier to support and protect the internal components. The energy storage battery pack 11, the controller 12, the fire protection component 15, the monitoring component 16, and the plurality of server bodies 17 are installed in the cabinet body 10. The energy storage battery pack 11 is separately connected to the energy storage battery pack 11, the fire protection component 15, the monitoring component 16, and the plurality of server bodies 17 by means of the controller 12.

The controller 12 is configured to supply power to a power-consuming module, i.e. the load. The controller 12 typically includes a main incoming switch, a UPS input/output switch, a UPS bypass switch, a lightning protection switch, an air-conditioning switch, a two-way PDU switch, and a lightning protector, etc. The monitoring component 16 is configured to provide online monitoring of operating environment inside the cabinet body 10, to make a comprehensive and intelligent analysis of various information, to timely give an alert on abnormal environmental parameters and unexpected situations, to collect information such as temperature and humidity, smoke, UPS, precision air conditioning, power distribution, access control and video inside the cabinet, and to provide unified management and protocol conversion. For example, the monitoring component 16 may include a temperature sensor and a smoke sensor, where the temperature sensor is configured to collect the temperature inside the cabinet body 10, and the smoke sensor is configured to detect whether fire breaks out inside the cabinet body 10. The fire protection component 15 is configured to enable a fire protection function based on a first detection result from the monitoring component 16. The first detection result may be a detection result indicating a fire hazard detected by the smoke sensor.

In one embodiment, the server integrated cabinet 1 may also include a refrigeration component 18 configured to refrigerate the plurality of server bodies 17 to meet normal operating environment. Specifically, the refrigeration component 18 is connected to the energy storage battery pack 11 and the controller 12, respectively. The refrigeration component 18 is configured to control the temperature inside the cabinet body 10 based on a second detection result from the monitoring component 16. The second detection structure may be understood as a temperature value detected by the temperature sensor.

Further, the server integrated cabinet 1 also includes a UPS component 19. The energy storage battery pack 11 and the external solar cell array 2 are connected to the controller 12 by means of the UPS component 19, such that the UPS component 19 provides uninterrupted power supply.

Further, an overcharge discharger may also be connected to the cabinet body 10, and the overcharge discharger is connected to the controller 12. As an electronic protection apparatus, the overcharge discharger is configured to monitor voltage or current changes during charging and discharging processes of the solar cell array 2 and the energy storage battery pack 11, to avoid exceeding a safety range, thereby protecting them against damage.

In one embodiment, the energy storage battery pack 11, the controller 12, the refrigeration component 18, the UPS component 19, the fire protection component 15, the monitoring component 16, and the plurality of server bodies 17 are arranged along a height direction of the cabinet body 10 to reduce occupied area. In this way, more server integrated cabinets 1 may be arranged within a preset site to increase capacity.

It should be pointed out that reference may be made to the existing technologies for specific structures of the fire protection component 15, the refrigeration component 18, and the UPS component 19, which are not to be described in detail here.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A server system at least comprising a server integrated cabinet and a solar cell array;
wherein the server integrated cabinet comprises an energy storage battery pack, a controller, and a load; and
the solar cell array, the energy storage battery pack, and the load are connected to the controller, respectively, such that the solar cell array and the energy storage battery pack supply power to the load.

2. The server system according to claim 1, wherein the solar cell array is connected to the controller by means of an anti-reverse charging diode, and the anti-reverse charging diode is configured to ensure an electric current to flow unidirectionally from the solar cell array to the controller.

3. The server system according to claim 2, wherein the load comprises a DC load; and
the controller is connected to the DC load, and a first control switch is connected in series between the controller and the DC load.

4. The server system according to claim 3, wherein the load comprises an AC load; and
the controller is connected to the AC load, and a second control switch and an inverter are connected in series between the controller and the AC load.

5. The server system according to claim 4 further comprising a backup energy source; wherein
the backup energy source is connected to the controller to supply power to the load by means of the controller.

6. A server integrated cabinet comprising a cabinet body, an energy storage battery pack, a controller, a fire protection component, a monitoring component, and a plurality of server bodies;
the energy storage battery pack, the controller, the fire protection component, the monitoring component, and the plurality of server bodies are installed in the cabinet body;
the energy storage battery pack is separately connected to the energy storage battery pack, the fire protection component, the monitoring component, and the plurality of server bodies by means of the controller; and
the fire protection component is configured to enable a fire protection function based on a first detection result from the monitoring component.

7. The server integrated cabinet according to claim 6 further comprising a refrigeration component; wherein
the refrigeration component is connected to the energy storage battery pack and the controller, respectively; and
the refrigeration component is configured to control a temperature inside the cabinet body based on a second detection result from the monitoring component.

8. The server integrated cabinet according to claim 7 further comprising a UPS component; wherein
the energy storage battery pack and the external solar cell array are connected to the controller by means of the UPS component.

9. The server integrated cabinet according to claim 8, wherein the energy storage battery pack, the controller, the refrigeration component, the UPS component, the fire protection component, the monitoring component, and the plurality of server bodies are arranged along a height direction of the cabinet body.

10. The server integrated cabinet according to claim 8, wherein the monitoring component comprises a temperature sensor and a smoke sensor.
